(19) United States
(12) Patent Application Publication
(10) Pub. No.: US 2026/0190436 A1
(43) Pub. Date: Jul. 2, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventor: Won Tae KOO, Icheon-si (KR)

(21) Appl. No.: 19/089,877

(22) Filed: Mar. 25, 2025

(30) Foreign Application Priority Data
Dec. 30, 2024 (KR) 10-2024-0199536

(51) Int. Cl. H10D 64/68; H10B 51/20; H10B 51/30; H10D 30/01; H10D 30/69; H10D 64/01

(52) U.S. Cl. CPC H10D 64/689; H10B 51/20; H10B 51/30; H10D 30/0415; H10D 30/701; H10D 64/033; H10D 64/685; H10D 64/687; H10D 64/691

(57) ABSTRACT

A semiconductor device includes a substrate including a source area and a drain area, a first dielectric layer disposed on the substrate, a second dielectric layer disposed on the first dielectric layer and including a porous material, a ferroelectric layer disposed on the second dielectric layer, and an electrode layer disposed on the ferroelectric layer.

### CROSS-REFERENCE TO RELATED APPLICATION

This application claims priority under 35 U.S.C. § 119 to Korean Patent Application No. 10-2024-0199536 filed in the Korean Intellectual Property Office on Dec. 30, 2024, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

The integration degree of a semiconductor device is mainly determined by an area occupied by a unit memory cell. Recently, as improvements in the integration degree of a semiconductor device in which a memory cell is formed as a single layer on a substrate reaches its limits, a three-dimensional semiconductor device in which memory cells are stacked on a substrate are being proposed. In addition, various structures and manufacturing methods are being developed in order to improve the reliability of operation the semiconductor device.

### SUMMARY

According to an embodiment of the present disclosure, a semiconductor device may include a substrate including a source area and a drain area, a first dielectric layer disposed on the substrate, a second dielectric layer disposed on the first dielectric layer and including a porous material, a ferroelectric layer disposed on the second dielectric layer, and an electrode layer disposed on the ferroelectric layer.

According to an embodiment of the present disclosure, a semiconductor device may include a gate structure including insulating layers and conductive layers alternately stacked, a channel layer extending through the gate structure, a first dielectric layer surrounding the channel layer, a second dielectric layer surrounding the first dielectric layer and including a porous material, and a ferroelectric layer surrounding the second dielectric layer.

According to an embodiment of the present disclosure, a method of manufacturing a semiconductor device may include forming a first dielectric layer on a substrate including a source area and a drain area, forming a second dielectric layer including a porous material on the first dielectric layer, forming a ferroelectric layer on the second dielectric layer, and forming an electrode layer on the ferroelectric layer.

According to an embodiment of the present disclosure, a method of manufacturing a semiconductor device may include forming a stack by alternately stacking first material layers and second material layers, forming a channel hole extending through the stack, forming a ferroelectric layer in the channel hole, forming a second dielectric layer including a porous material on the ferroelectric layer, forming a first dielectric layer on the second dielectric layer, and forming a channel layer on the first dielectric layer.

### BRIEF DESCRIPTION OF THE DRAWINGS

FIG. 1 is a drawing illustrating a semiconductor device according to an embodiment of the present disclosure.

FIGS. 2A and 2B are drawings schematically illustrating a semiconductor device according to an embodiment of the present disclosure.

FIGS. 3A to 3C, 4A, 4B, 5A, 5B, 6A, and 6B are schematic drawings used to compare semiconductor devices according to embodiments of the present disclosure.

FIG. 7 is a schematic cross-section illustrating a method of manufacturing a semiconductor device according to an embodiment of the present disclosure.

FIGS. 8A, 8B, 9A, and 9B are schematically illustrating a method of manufacturing a semiconductor device according to an embodiment of the present disclosure.

### DETAILED DESCRIPTION

An embodiment of the present disclosure provides a semiconductor device having a more stable structure and improved characteristics and a method of manufacturing the semiconductor device.

According to the present technology, a semiconductor device having a more stable structure and improved reliability may be provided.

Hereinafter, embodiments according to the technical spirit of the present disclosure are described with reference to the accompanying drawings.

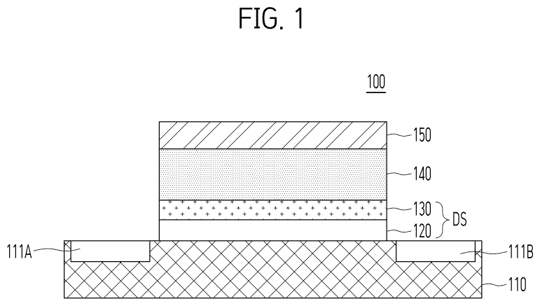

FIG. 1 is a drawing illustrating a semiconductor device according to an embodiment of the present disclosure.

Referring to FIG. 1, a semiconductor device 100 may include a substrate 110, a dielectric structure DS, a ferroelectric layer 140, and an electrode layer 150.

The substrate 110 may include a semiconductor substrate such as a silicon substrate. The substrate 110 may include a conductive area. For example, the substrate 110 may include a source area 111A and a drain area 111B. Here, the source area 111A and the drain area 111B may be located spaced apart from each other in the substrate 110. A current may flow between the source area 111A and the drain area 111B, and thus a channel may be formed. The substrate 110 may include polysilicon.

The dielectric structure DS may include a first dielectric layer 120 and a second dielectric layer 130. The first dielectric layer 120 may be located on the substrate 110. For example, the first dielectric layer 120 may be located on the substrate 110 and between the source area 111A and the drain area 111B. The first dielectric layer 120 may include an insulating material such as oxide. For example, the first dielectric layer 120 may include silicon oxide. The first dielectric layer 120 may include SiO₂. Here, a dielectric constant of SiO₂ may be 3.9.

The second dielectric layer 130 may be located on the first dielectric layer 120. The second dielectric layer 130 may include a material different from a material of the first dielectric layer 120. For example, the second dielectric layer 130 may include a porous material. Here, the porous material may mean a multi-pore material. For example, the second dielectric layer 130 may include a porous organic framework. The second dielectric layer 130 may include at least one of a metal-organic-framework (MOF) or a covalent-organic-framework (COF).

A dielectric constant of the second dielectric layer 130 may be less than a dielectric constant of the first dielectric layer 120. For example, the dielectric constant of the second dielectric layer 130 may be less than 2. This is because a dielectric constant of air included in the porous material is 1. In other words, the second dielectric layer 130 may include an ultra-low-k material.

The ferroelectric layer 140 may be located on the dielectric structure DS. For example, the ferroelectric layer 140 may be located on the second dielectric layer 130. The ferroelectric layer 140 may be used as a data storage layer. For example, after an external electric field with a positive polarity or a negative polarity is applied to the ferroelectric layer 140, the ferroelectric layer 140 may store data in a bit form by using residual polarization that is maintained after the external electric field is removed. For example, a positive state or a negative state of the ferroelectric layer 140 may be stored as data in a bit form such as ‘0’ or ‘1’. Therefore, the ferroelectric layer 140 may include a ferroelectric material that may maintain residual polarization even after the external electric field is removed. For example, the ferroelectric layer 140 may include metal oxide. The ferroelectric layer 140 may include hafnium oxide, zirconium oxide, or the like.

A multi-level memory cell may be configured by storing multi-bit data in a ferroelectric layer according to a write voltage condition (size, application time, number of times, and the like) of the semiconductor device. For example, when a memory cell has four states and may store two bits of data per memory cell, data of ‘11’ may be stored by applying a first write voltage corresponding to a first state to the memory cell, data of ‘01’ may be stored by applying a second write voltage corresponding to a second state to the memory cell, data of ‘10’ may be stored by applying a third write voltage corresponding to a third state to the memory cell, and data of ‘00’ may be stored by applying a fourth write voltage corresponding to a fourth state to the memory cell. However, the bit form is not limited to ‘11, 01, 10, 00’. For example, the memory cell may have four or more states and may have a form of two or more bits per memory cell.

In addition, an analog-computation in memory (A-CIM) oriented semiconductor device that performs a matrix operation in the memory cell by using a conductance of the semiconductor device as a weight and a read voltage applied to the semiconductor device as an input may be configured. When the degree change in the conductance of a semiconductor device is rapid according to the applied read voltage, a limit exists in maintaining performance of the semiconductor device. For example, when electrical conductivity of the semiconductor device changes rapidly, a limit exists in implementing a plurality of multi-level memory cells in a set range of read voltage. Therefore, in order to maintain or improve performance of the semiconductor device, the conductance and its rate of change are need to be appropriately managed with respect to read voltage level applied in a set range of bias.

According to an embodiment of the present disclosure, a semiconductor device 100 may include a dielectric structure DS, and the dielectric structure DS may include a first dielectric layer 120 and a second dielectric layer 130. The semiconductor device 100 may have a greater thickness when the dielectric structure DS includes the first dielectric layer 120 and the second dielectric layer 130 than when the dielectric structure DS includes a single first dielectric layer 120. In addition, the semiconductor device 100 may have a dielectric structure DS with a less than average dielectric constant by locating the second dielectric layer 130 on the first dielectric layer 120.

When a thickness of the dielectric structure DS increases and a dielectric constant decreases, the size of an on current of the semiconductor device 100 may decrease. Here, the on current may mean a size of a current flowing in the semiconductor device 100 in operational states. In embodiments of the disclosure, the semiconductor device 100 may configure a multi-level memory cell even in with a small amount of current. In addition, by decreasing the on current of the semiconductor device 100, power consumption of the semiconductor device 100 may be decreased, which may improve energy efficiency when performing a matrix operation, such as vector matrix multiplication (VMM), in the memory cell.

When a capacitance of the dielectric structure DS included in the semiconductor device 100 decreases, the on current of the semiconductor device 100 may decrease. In addition, when the capacitance of the dielectric structure DS decreases, a change in the amount of conductance for a change in the applied read voltage may be relatively decreased. In other words, a change degree of electrical conductivity for the change of the applied read voltage may be small. As such, in implementing a multi-level memory cell, the conductance of the semiconductor device 100 may be relatively well maintained even against noise, and thus reliability of the A-CIM oriented semiconductor device 100 may be improved.

In summary, according to embodiments of the present disclosure, a semiconductor device 100 may implement a multi-level memory cell with a small amount of current, reduce power consumption, and improve reliability of an A-CIM oriented semiconductor device.

The electrode layer 150 may be located on the ferroelectric layer 140. The electrode layer 150 may include a conductive material. The electrode layer 150 may include a metal material. For example, the electrode layer 170 may include a conductive material such as tungsten.

According to the structure described above, a semiconductor device 100 may include a dielectric structure DS including a first dielectric layer 120 and a second dielectric layer 130. Here, the second dielectric layer 130 may include a porous material. In other words, the second dielectric layer 130 may include an ultra-low dielectric material. By including an ultra-low dielectric material in the second dielectric layer 130, a semiconductor device 100 may configure a multi-level memory cell even with a small amount of current, and may reduce power consumption. In addition, performance of an A-CIM oriented semiconductor device 100 may be improved.

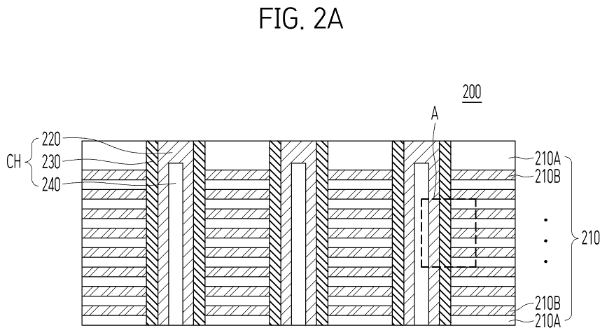

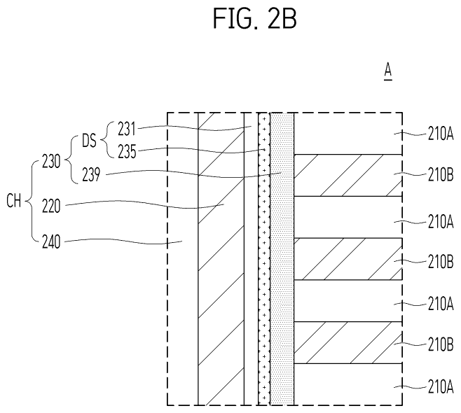

FIGS. 2A and 2B are drawings schematically illustrating a semiconductor device according to an embodiment of the present disclosure. FIG. 2A is a cross-sectional view, and FIG. 2B is an enlarged view of a part A of FIG. 2A. Hereinafter, content that overlaps the content described above with reference to FIG. 1 may be omitted for convenience and clarity.

Referring to FIGS. 2A and 2B, a semiconductor device 200 may include a gate structure 210 and a channel structure CH.

The gate structure 210 may include insulating layers 210A and conductive layers 210B, which are alternately stacked. The insulating layers 210A may include an insulating material such as oxide, and the conductive layers 210B may include a conductive material such as tungsten, molybdenum, or polysilicon. The conductive layers 210B may be a gate line such as a source selection line, a word line, or a drain selection line. A source selection transistor, a memory cell, or a drain selection transistor may be located in an area where the channel structures CH and the conductive layers 210B intersect. For example, at least one source selection transistor, a plurality of memory cells, and at least one drain selection transistor stacked along the channel structure CH may configure one memory string.

The channel structure CH may extend through the gate structure 210. The channel structure CH may include a channel layer 220 and a memory layer 230 surrounding the channel layer 220. The channel structure CH may further include an insulating core 240 located in the channel layer 220. Here, the channel layer 220 may include a semiconductor material such as polysilicon or germanium. The insulating core 240 may include an insulating material such as oxide.

Referring to FIG. 2B, the memory layer 230 may include a dielectric structure DS and a ferroelectric layer 239. Here, the dielectric structure DS may include a first dielectric layer 231 and a second dielectric layer 235. The first dielectric layer 231, the second dielectric layer 235, and the ferroelectric layer 239 may sequentially surround the channel layer 220.

The first dielectric layer 231 may surround the channel layer 220 and may include an insulating material such as oxide. For example, the first dielectric layer 231 may include silicon oxide. The first dielectric layer 231 may include SiO₂. The second dielectric layer 235 may surround the first dielectric layer 231 and may include a material different from a material of the first dielectric layer 231. For example, the second dielectric layer 235 may include a porous organic framework. The second dielectric layer 235 may include at least one of a metal-organic-framework (MOF) or a covalent-organic-framework (COF). A dielectric constant of the second dielectric layer 235 may be less than a dielectric constant of the first dielectric layer 231. For example, the dielectric constant of the second dielectric layer 235 may be less than 2.

The ferroelectric layer 239 may surround the second dielectric layer 235 and may include a ferroelectric material. For example, the ferroelectric layer 239 may include metal oxide. The ferroelectric layer 239 may include hafnium oxide, zirconium oxide, or the like.

According to an embodiment of the present disclosure, a semiconductor device 200 may include the dielectric structure DS, and the dielectric structure DS may include the first dielectric layer 231 and the second dielectric layer 235. With two dielectric layers, an average dielectric constant for the dielectric structure DS may be decreased because the thickness of the dielectric structure DS may be greater than the thickness of a single layer of either the first dielectric layer 231 or the second dielectric layer 235.

When the thickness of the dielectric structure DS is increased and a dielectric constant is decreased, the size of an on current used in the semiconductor device 200 may be decreased. In addition, a capacitance of the semiconductor device 200 may be decreased, and a change amount of a conductance may be decreased. As a result, power consumption of the semiconductor device 200 may be decreased, and reliability of the A-CIM oriented semiconductor device 200 may be improved.

According to the structures described above, memory cells may be located in an area where the channel structures CH and the conductive layers 210B intersect. The stacked memory cells may share the first dielectric layer 231, the second dielectric layer 235, and the ferroelectric layer 239.

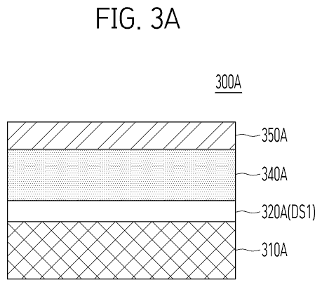

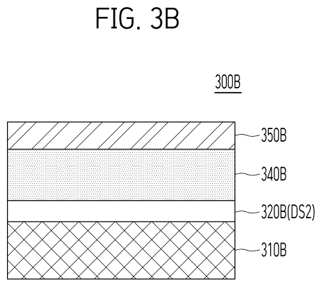

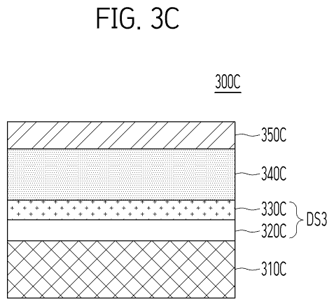

FIGS. 3A to 3C, 4A, 4B, 5A, 5B, 6A, and 6B are schematic drawings used to compare semiconductor devices according to embodiments of the present disclosure. Hereinafter, content that overlaps the content described above may be omitted for convenience and clarity.

Referring to FIG. 3A, a semiconductor device 300A includes a substrate 310A, a first dielectric layer 320A, a ferroelectric layer 340A, and an electrode layer 350A. The first dielectric layer 320A, the ferroelectric layer 340A, and the electrode layer 350A are sequentially stacked on the substrate 310A.

Referring to FIG. 3B, a semiconductor device 300B includes a substrate 310B, a first dielectric layer 320B, a ferroelectric layer 340B, and an electrode layer 350B. The first dielectric layer 320B, the ferroelectric layer 340B, and the electrode layer 350B are sequentially stacked on the substrate 310B.

Comparing FIG. 3A and FIG. 3B, substrate 310A includes single-crystal silicon, and substrate 310B includes polycrystalline silicon. For example, when substrate 310B includes polysilicon, which is polycrystalline silicon, charge mobility is lower than charge mobility in a substrate of single-crystal silicon. In other words, charge mobility in substrate 310B is lower than charge mobility in substrate 310A. As a result, an on current of the semiconductor device 300B is relatively less than an on current of the semiconductor device 300A. Therefore, power consumption of the semiconductor device 300B is less than power consumption of the semiconductor device 300A.

The first dielectric layer 320A includes substantially the same material as the first dielectric layer 320B. For example, the first dielectric layers 320A and 320B include silicon oxide. The ferroelectric layer 340A includes substantially the same material as the ferroelectric layer 340B. For example, the ferroelectric layers 340A and 340B include metal oxide. The electrode layer 350A includes substantially the same material as the electrode layer 350B. For example, the electrode layers 350A and 350B include a conductive material.

Referring to FIG. 3C, a semiconductor device 300C includes a substrate 310C, a first dielectric layer 320C, a second dielectric layer 330C, a ferroelectric layer 340C, and an electrode layer 350C. The first dielectric layer 320C, the second dielectric layer 330C, the ferroelectric layer 340C, and the electrode layer 350C are sequentially stacked on the substrate 310C.

The first dielectric layer 320C includes substantially the same material as the first dielectric layers 320A and 320B. The ferroelectric layer 340C includes substantially the same material as the ferroelectric layers 340A and 340B. The electrode layer 350C includes substantially the same material as the electrode layers 350A and 350B.

The substrate 310C includes substantially the same material as the substrate 310B. For example, the substrate 310C includes polysilicon, and so an on current of the semiconductor device 300C is decreased, and power consumption is decreased.

The semiconductor device 300C further includes a second dielectric layer 330C compared to the semiconductor devices 300A and 300B. The second dielectric layer 330C includes a material different from a material of the first dielectric layers 320A and 320B, 320C. The second dielectric layer 330C includes a porous organic framework. For example, the second dielectric layer 330C includes at least one of a metal-organic-framework (MOF) or a covalent-organic-framework (COF).

In addition, a dielectric constant of the second dielectric layer 330C is less than a dielectric constant of the first dielectric layers 320A, 320B, and 320C. The dielectric constant of the first dielectric layers 320A, 320B, and 320C is between 2 and 4. For example, the dielectric constant of the first dielectric layers 320A, 320B, and 320C is 3.9. The dielectric constant of the second dielectric layer 330C, however, is less than 2.

In other words, the semiconductor device 300C includes a dielectric structure DS3 including a first dielectric layer 320C and a second dielectric layer 330C. The thickness of the dielectric structure DS3 is greater than the thickness of a dielectric structure DS1 including the first dielectric layer 320A and a dielectric structure DS2 including the first dielectric layer 320B. In addition, because the dielectric structure DS3 includes the second dielectric layer 330C, which has a dielectric constant relatively less than a dielectric constant of the first dielectric layers 320A, 320B, and 320C, an average dielectric constant of the dielectric structure DS3 is less than an average dielectric constant of the dielectric structure DS1 and the dielectric structure DS2.

Referring to FIGS. 3A to 3C, 4A, 5A, and 5B, a size of an on current I_{d} of the semiconductor devices 300A, 300B, and 300C changes depending on the substrates 310A, 310B, and 310C and the dielectric structures DS1, DS2, and DS3 used in the semiconductor devices 300A, 300B, and 300C.

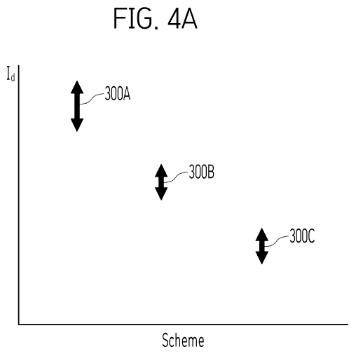

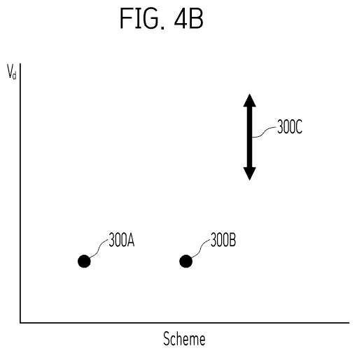

Charge mobility is less and an on current is lower when a substrate of a semiconductor device includes polycrystalline silicon, as compared to a semiconductor device in which the substrate includes single-crystal silicon. For example in FIG. 4A, an on current I_{d} of the semiconductor devices 300B and 300C is less than an on current of the semiconductor device 300A.

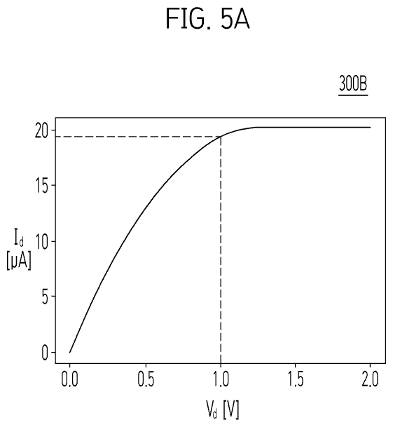

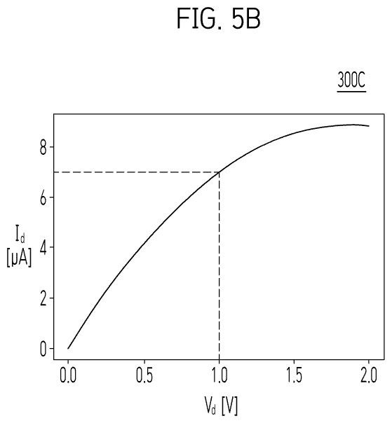

In addition, as the relative thickness of a dielectric structure of a semiconductor device increases and a dielectric constant decreases, an on current is decreased. For example, the on current of the semiconductor device 300C is less than the on current of the semiconductor device 300B. Referring to FIGS. 5A and 5B, when a voltage V_{d} of 1 V is applied, the on current I_{d} of the semiconductor device 300B is about 19^{μA} in FIG. 5A and the on current I_{d} of the semiconductor device 300C is about 7^{μA} in FIG. 5B.

According to an embodiment of the present disclosure, semiconductor device 300C includes a substrate 310C with polycrystalline silicon and includes a dielectric structure DS3 having a relatively greater thickness and a relatively lower dielectric constant compared to semiconductor devices 300A and 300B. As a result, the on current of the semiconductor device 300C is less than the on current of the semiconductor devices 300A and 300B. Therefore, power consumption of the semiconductor device 300C is less than power consumption of the semiconductor devices 300A and 300B. In addition, the semiconductor device 300C may implement a multi-level memory cell in amounts of current less than the size of a current of the semiconductor devices 300A and 300B.

Referring to FIGS. 3A to 3C, 4A, 4B, 6A and 6B, performance of an A-CIM oriented semiconductor device may vary according to the dielectric structures DS1, DS2, and DS3 of the semiconductor devices 300A, 300B, and 300C.

As the thickness of a dielectric structure of a semiconductor device decreases and as the dielectric constant increases, capacitance is increased and an on current of the semiconductor device is increased. When the capacitance of the semiconductor device increases, the amount of the conductance change for a change to the applied bias increases. Therefore, when utilizing multiple conductance levels to implement an A-CIM oriented multi-level memory cell, there are limitations to maintaining semiconductor performance. For example, because changes in conductance may be rapid according to read voltage changes when changing to multiple conductance levels within a set range, semiconductor performance can be limited with respect to maintaining the same conductance state due to noise.

On the other hand, as the thickness of the dielectric structure of the semiconductor device is increased and the dielectric constant is decreased, the capacitance of the semiconductor device is decreased and the on current is decreased. When the capacitance of the semiconductor device is decreased, the amount of change in conductance for a change in the applied bias is decreased. In other words, a change degree of electrical conductivity of the semiconductor device for the change of the bias applied to the semiconductor device decreases. Thus, when utilizing multiple conductance levels, the conductance of the semiconductor device may be maintained in a relatively more stable manner, and thus performance of the semiconductor device may be maintained and improved.

As discussed above, the semiconductor device 300C includes the dielectric structure DS3 having a relatively greater thickness and a relatively lower dielectric constant than the semiconductor devices 300A and 300B. The semiconductor device 300C has a relatively less on current than the semiconductor devices 300A and 300B, and the degree of change in conductance is not large with respect to a change in applied bias. Therefore, because the semiconductor device 300C may secure a relatively constant conductance, even with changes a plurality of voltage levels in a set range, performance is maintained and improved in an A-CIM oriented semiconductor device compared to the semiconductor devices 300A and 300B.

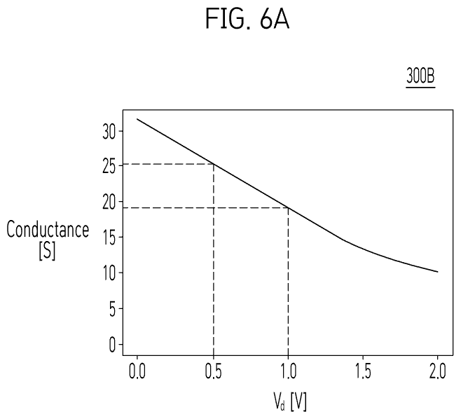

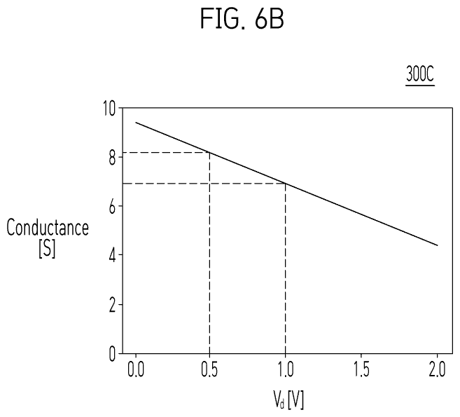

Referring to FIGS. 6A and 6B, when a read voltage V_{d} applied to a semiconductor device 300B changes from 0.5 V to 1 V, conductance S changes from about 25 S to about 18 S. When a read voltage is applied to a semiconductor device 300C changes from 0.5 V to 1 V, however, the conductance changes from about 8 S to about 7 S. Therefore, the semiconductor device 300C is more suitable for use in an A-CIM oriented implementation of multi-level memory cell than the semiconductor devices 300A and 300B because the change in conductance is lower for the given voltage change. In FIGS. 6A and 6B, a unit [S] means [μS].

According to an embodiment of the present disclosure, because the semiconductor device 300C includes the dielectric structure DS3 having a relatively greater thickness and a relatively lower dielectric constant than semiconductor devices 300 A and 300B, an on-current, a capacitance, and a change amount of a conductance for an applied bias are relatively lower. Therefore, the semiconductor device 300C is more suitable for implementing an A-CIM oriented multi-level memory cell.

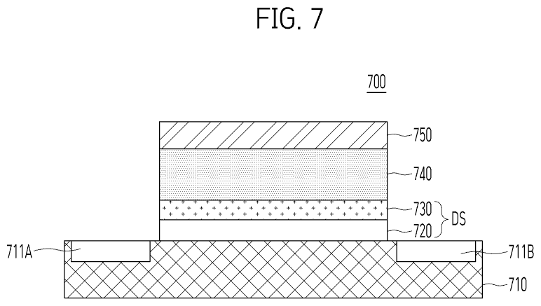

FIG. 7 is a schematic cross-section illustrating a method of manufacturing a semiconductor device according to an embodiment of the present disclosure. Hereinafter, content that overlaps with content described above is omitted for convenience and clarity.

Referring to FIG. 7, a first dielectric layer 720 may be formed on a substrate 710 in a semiconductor device 700. Here, the substrate 710 may include a semiconductor substrate such as a silicon substrate. The substrate 710 may include a source area 711A and a drain area 711B. The source area 711A and the drain area 711B may be formed to be spaced apart from each other in the substrate 710. The substrate 710 may be polycrystalline silicon and may include polysilicon.

The first dielectric layer 720 may be located on the substrate 710 and may be formed between the source area 711A and the drain area 711B. The first dielectric layer 720 may include an insulating material such as oxide. For example, the first dielectric layer 720 may include silicon oxide. The first dielectric layer 720 may include SiO₂. Here, a dielectric constant of SiO₂ may be 3.9.

Subsequently, a second dielectric layer 730 may be formed on the first dielectric layer 720. Accordingly, a dielectric structure DS including the first dielectric layer 720 and the second dielectric layer 730 may be formed. The second dielectric layer 730 may include a porous material. For example, the second dielectric layer 730 may include a porous organic framework. The second dielectric layer 730 may include at least one of a metal-organic-framework (MOF) or a covalent-organic-framework (COF).

A dielectric constant of the second dielectric layer 730 may be less than a dielectric constant of the first dielectric layer 720. Because a dielectric constant of air included in a porous material is 1, for example, the dielectric constant of the second dielectric layer 730 may be less than 2. In other words, the second dielectric layer 730 may include an ultra-low-k material.

According to an embodiment of the present disclosure, the dielectric structure DS including the first dielectric layer 720 and the second dielectric layer 730 may be stacked over the substrate 710. A thickness of the semiconductor device 700 in the stack direction may be increased compared to a case where the dielectric structure DS is formed as a single first dielectric layer 720. In addition, by forming the second dielectric layer 730 on the first dielectric layer 720, an average dielectric constant of the dielectric structure DS of the semiconductor device 700 may be decreased.

When the thickness of the dielectric structure DS is increased and the dielectric constant is decreased, a size of an on current of the semiconductor device 700 may be decreased. As a result, the semiconductor device 700 may form a multi-level memory cell even if the current size is small. In addition, power consumption of the semiconductor device 700 may be decreased by decreasing the on current of the semiconductor device 700.

When a capacitance of the semiconductor device 700 is decreased, the on current of the semiconductor device 700 may be decreased. When the capacitance is decreased, the amount of change in conductance for a set amount of change in an applied bias may be decreased. As a result, in implementing a multi-level memory cell, when utilizing a plurality of conductance levels in a set range of read voltage, the conductance of the semiconductor device 700 may be more stably maintained. Therefore, performance of an A-CIM oriented semiconductor device 700 may be maintained and improved compared to a case where the change amount of the conductance is greater with respect to changes of the applied bias.

Subsequently, a ferroelectric layer 740 may be formed on the second dielectric layer 730. The ferroelectric layer 740 may be used as a data storage layer. The ferroelectric layer 740 may include a metal oxide. The ferroelectric layer 740 may include hafnium oxide, zirconium oxide, or the like.

Subsequently, an electrode layer 750 may be formed on the ferroelectric layer 740. The electrode layer 750 may include a conductive material. The electrode layer 750 may include a metal material. For example, the electrode layer 770 may include a conductive material such as tungsten.

According to the manufacturing method described above, the second dielectric layer 730 including a porous material may be formed on the first dielectric layer 720. As the thickness of the dielectric structure DS increases, an average dielectric constant decreases, and an on current of the semiconductor device 700 may be decreased. Therefore, power consumption of the semiconductor device 700 may be decreased, and performance as an A-CIM oriented multi-level memory cell may be maintained and improved.

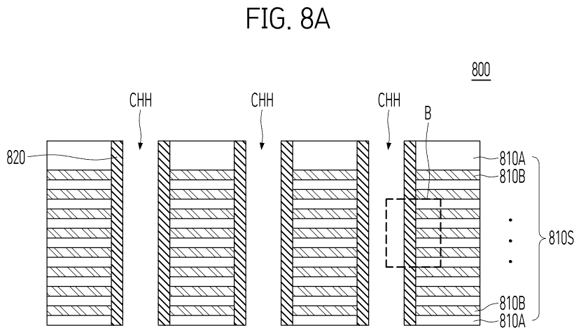

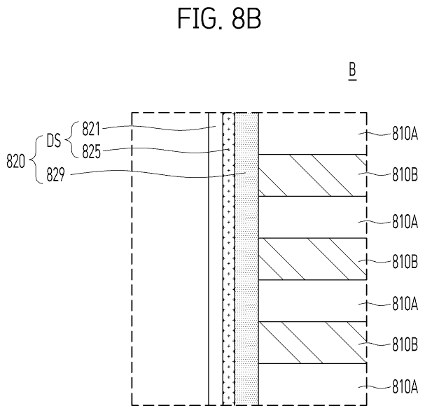

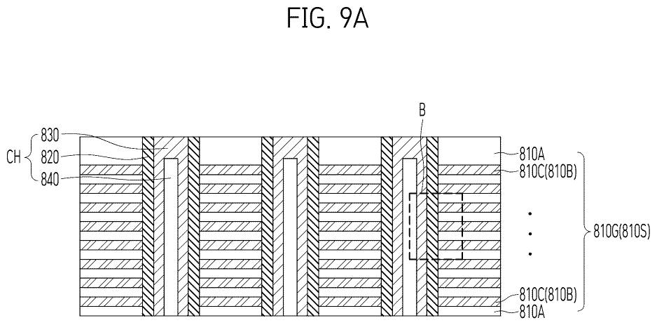

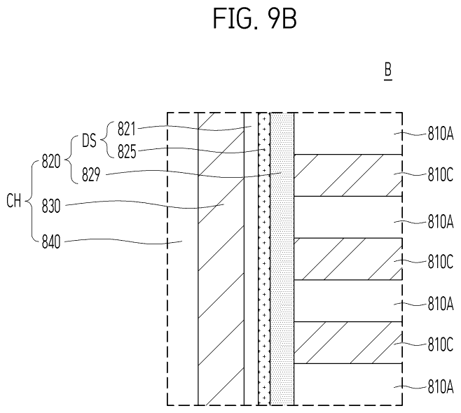

FIGS. 8A, 8B, 9A, and 9B are schematically illustrating a method of manufacturing a semiconductor device according to an embodiment of the present disclosure. FIGS. 8A and 9A are cross-sectional views, and FIGS. 8B and 9B are enlarged views of an area B of respective FIGS. 8A and 9A. Hereinafter, content that overlaps with the content described above is omitted for convenience and clarity.

Referring to FIGS. 8A and 8B, first material layers 810A and second material layers 810B may be alternately stacked to form a stack 810S. The first material layers 810A may include an insulating material such as oxide, and the second material layers 810B may include a sacrificial material such as nitride.

A channel hole CHH extending through the stack 810S may be formed. Subsequently, a memory layer 820 may be formed in the channel hole CHH. First, a ferroelectric layer 829 may be formed on sidewalls of the stack common to the channel hole CHH. Here, the ferroelectric layer 829 may be used as a data storage layer. The ferroelectric layer 829 may include a metal oxide. The ferroelectric layer 829 may include hafnium oxide, zirconium oxide, or the like.

Subsequently, a second dielectric layer 825 including a porous material may be formed on the ferroelectric layer 829. The second dielectric layer 825 may include a porous material. For example, the second dielectric layer 825 may include a porous organic framework. The second dielectric layer 825 may include at least one of a metal-organic-framework (MOF) or a covalent-organic-framework (COF). A dielectric constant of the second dielectric layer 825 may be less than 2 because a dielectric constant of air included in the porous material is 1. In other words, the second dielectric layer 825 may include an ultra-low-k material.

Subsequently, a first dielectric layer 821 may be formed on the second dielectric layer 825. Accordingly, a dielectric structure DS including the first dielectric layer 821 and the second dielectric layer 825 may be formed, and a memory layer 820 including the first dielectric layer 821, the second dielectric layer 825, and the ferroelectric layer 829 may be formed. The first dielectric layer 821 may include silicon oxide. The first dielectric layer 821 may include SiO₂. For example, a dielectric constant of SiO₂ in the first dielectric layer 821 may be 3.9.

Referring to FIGS. 9A and 9B, a channel layer 830 may be formed on the memory layer 820. For example, the channel layer 830 may be formed on the first dielectric layer 821. Subsequently, an insulating core 840 may be formed in the channel layer 830. Accordingly, a channel structure CH including the memory layer 820, the channel layer 830, and the insulating core 840 may be formed. The channel layer 830 may include a semiconductor material such as polysilicon or germanium, and the insulating core 840 may include an insulating material such as oxide.

Subsequently, the second material layers 810B may be replaced with third material layers 810C through a slit (not shown). For example, after the second material layers 810B are removed via the slit, the third material layers 810C may be formed in areas from which the second material layers 810B are removed. Here, the third material layers 810C may be used as a gate line and may include a conductive material. Accordingly, a gate structure 810G including the first material layers 810A and the third material layers 810C, alternately stacked, may be formed. In the device, when the second material layers 810B include a conductive material, a process of replacing the second material layers 810B with the third material layers 810C may be omitted. In such cases, the stack 810S may be used as the gate structure 810G.

According to an embodiment of the present disclosure, a dielectric structure DS including a first dielectric layer 821 and a second dielectric layer 825 may be formed. A thickness of the semiconductor device 800 may be increased compared to devices in which the dielectric structure DS is formed as a single first dielectric layer 821. In addition, an average dielectric constant of the dielectric structure DS of the semiconductor device 700 may be decreased by forming the second dielectric layer 825 on the first dielectric layer 821.

When a thickness of the dielectric structure DS is increased and a dielectric constant is decreased, a size of an on current of the semiconductor device 800 may be decreased. As a result, the semiconductor device 800 may form a multi-level memory cell even that can store multi-level information using small amounts of current. In addition, power consumption of the semiconductor device 800 may be decreased by decreasing the on current of the semiconductor device 800.

When a capacitance of the semiconductor device 800 is decreased, the on current of the semiconductor device 800 may be decreased. When the capacitance is decreased, a change amount of a conductance in relation to a change of an applied bias may be decreased. Thus, in implementing a multi-level memory cell that utilizes a plurality of conductance levels in a set range of read voltage, a conductance of the semiconductor device 800 may be more stably maintained. Therefore, performance of the A-CIM oriented semiconductor device 800 may be maintained and improved compared to semiconductor devices in which a change of electrical conductivity is greater with respect to the same amount change in the applied bias.

According to the manufacturing methods described above, memory cells may be located in areas where the channel structures CH and the third material layers 810C intersect. The stacked memory cells may share the first dielectric layer 821, the second dielectric layer 825, and the ferroelectric layer 829.

Although embodiments according to the technical spirit of the present disclosure have been described with reference to the accompanying drawings, this is only for describing an embodiment according to the concepts of the present disclosure, and the present disclosure is not limited to the above-described embodiments. In the scope of the technical spirit of the present disclosure described in the claims, various forms of substitution, modification, and change of the embodiments will be possible by those skilled in the art to which the present disclosure belongs, and these embodiments also belong to the scope of the present disclosure.

What is claimed is:

1. A semiconductor device comprising:
a substrate including a source area and a drain area;
a first dielectric layer disposed on the substrate;
a second dielectric layer disposed on the first dielectric layer and including a porous material;
a ferroelectric layer disposed on the second dielectric layer; and
an electrode layer disposed on the ferroelectric layer.

2. The semiconductor device of claim 1, wherein the second dielectric layer includes a porous organic framework.

3. The semiconductor device of claim 2, wherein the second dielectric layer includes a metal-organic-framework (MOF).

4. The semiconductor device of claim 2, wherein the second dielectric layer includes a covalent-organic-framework (COF).

5. The semiconductor device of claim 1, wherein a dielectric constant of the second dielectric layer is less than a dielectric constant of the first dielectric layer.

6. The semiconductor device of claim 5, wherein the dielectric constant of the second dielectric layer is less than 2.

7. The semiconductor device of claim 1, wherein the substrate includes polysilicon.

8. The semiconductor device of claim 1, wherein the source area and the drain area are spaced apart from each other in the substrate.

9. The semiconductor device of claim 1, wherein the first dielectric layer is disposed on the substrate between the source area and the drain area.

10. A semiconductor device comprising:
a gate structure including insulating layers and conductive layers alternately stacked;
a channel layer extending through the gate structure;
a first dielectric layer surrounding the channel layer;
a second dielectric layer surrounding the first dielectric layer and including a porous material; and
a ferroelectric layer surrounding the second dielectric layer.

11. The semiconductor device of claim 10, wherein the second dielectric layer includes a porous organic framework.

12. The semiconductor device of claim 11, wherein the second dielectric layer includes a metal-organic-framework (MOF).

13. The semiconductor device of claim 11, wherein the second dielectric layer includes a covalent-organic-framework (COF).

14. The semiconductor device of claim 10, wherein a dielectric constant of the second dielectric layer is less than a dielectric constant of the first dielectric layer.

15. The semiconductor device of claim 14, wherein the dielectric constant of the second dielectric layer is less than 2.

16. A method of manufacturing a semiconductor device, the method comprising:
forming a first dielectric layer on a substrate including a source area and a drain area;
forming a second dielectric layer including a porous material on the first dielectric layer;
forming a ferroelectric layer on the second dielectric layer; and
forming an electrode layer on the ferroelectric layer.

17. The method of claim 16, wherein the second dielectric layer includes a porous organic framework.

18. The method of claim 17, wherein the second dielectric layer includes a metal-organic-framework (MOF).

19. The method of claim 17, wherein the second dielectric layer includes a covalent-organic-framework (COF).

20. The method of claim 16, wherein a dielectric constant of the second dielectric layer is less than a dielectric constant of the first dielectric layer.

21. The method of claim 20, wherein the dielectric constant of the second dielectric layer is less than 2.

22. The method of claim 16, wherein the substrate includes polysilicon.

23. The method of claim 16, wherein the source area and the drain area are formed spaced apart from each other in the substrate.

24. The method of claim 16, wherein the first dielectric layer is formed between the source area and the drain area.

25. A method of manufacturing a semiconductor device, the method comprising:
forming a stack by alternately stacking first material layers and second material layers;
forming a channel hole extending through the stack;
forming a ferroelectric layer in the channel hole;
forming a second dielectric layer including a porous material on the ferroelectric layer;
forming a first dielectric layer on the second dielectric layer; and
forming a channel layer on the first dielectric layer.

26. The method of claim 25, wherein the second dielectric layer includes a porous organic framework.

27. The method of claim 26, wherein the second dielectric layer includes a metal-organic-framework (MOF).

28. The method of claim 26, wherein the second dielectric layer includes a covalent-organic-framework (COF).

29. The method of claim 25, wherein a dielectric constant of the second dielectric layer is less than a dielectric constant of the first dielectric layer.

30. The method of claim 29, wherein the dielectric constant of the second dielectric layer is less than 2.
